(19) United States
(12) Patent Application Publication
(10) Pub. No.: US 2026/0333631 A1
(43) Pub. Date: Oct. 22, 2026

(54) ADJUSTABLE JOULE THOMPSON COOLING OF ELECTRONIC DEVICES

(71) Applicant: Flowserve Pte. Ltd., Singapore (SG)

(72) Inventor: Michael Albert Mancuso, Coppell, TX (US)

(73) Assignee: Flowserve Pte. Ltd., Singapore (SG)

(21) Appl. No.: 19/186,073

(22) Filed: Apr. 22, 2025

(51) Int. Cl. H05K 7/20

(52) U.S. Cl. CPC H05K 7/20327; H05K 7/20381

(57) ABSTRACT

An electronic device cooling system conserves energy by directing a coolant gas through cooling outlets comprising fixed or adjustable Joule-Thompson constrictions. An upstream secondary pre-cooling Joule-Thompsen constriction can be included. A pressure and/or flow control device, such as a valve or variable speed pump, can be adjustable by a controller to vary cooling rates and distribution according to changing requirements. The coolant gas can be applied directly to the devices, to dry heat sinks applied to the devices, or to a cooling liquid film provided on the devices or heat sinks. The liquid cooling film can be derived by liquifying a portion of the circulating coolant gas. The cooling loop can be branched into flow paths, each of which can be separately controlled. The cooling can be adjusted reactively according to temperature measurements, and/or predictively according to measured electrical current flows to the electronic devices and/or device workload predictions.

### FIELD OF THE INVENTION

The invention relates to cooling of electronic devices, and more particularly to cooling of electronic devices by a circulated coolant.

### BACKGROUND OF THE INVENTION

Many electronic systems, including most computers, comprise some sort of cooling mechanism designed to moderate the temperatures of the integrated circuits (ICs) and other electronic elements included in the device, as well as the overall temperature within the device housing. For example, most laptop and desktop computers include at least one fan that circulates ambient air throughout the housing interior. In addition, devices with high power consumption, such as central processing units (CPUs), often include dedicated fans to ensure that they do not overheat.

This “forced air convection” approach is effective for many individual electronic systems having housings that are surrounded by a large volume of ambient air. However, forced air convection may be insufficient for cooling large “clusters” or “arrays” of components or devices that are closely spaced together, and fill most of the volume within a room or building. In particular, cooling of so-called “data centers,” “server farms” artificial intelligence (AI) systems, and “super-computers” (referred to herein collectively as “data centers”) can be challenging. In such cases, cooling of the electronic devices by a chilled and circulated coolant can be necessary.

Data centers are one of the most energy-intensive building usage types, consuming from 10 to 50 times as much energy per square foot as a typical commercial office building. Collectively, data centers account for approximately 2% of the total U.S. electricity usage, and this figure is expected to increase as data centers become more numerous, due in part to the rapid increase in artificial intelligence systems.

While much of the energy that is consumed by a data center is due to the power consumed and dissipated by the electronic devices themselves, a significant amount of energy is also consumed by the cooling systems that are required for removing the dissipated energy from the electronics. Accordingly, there is a need to optimize the energy efficiency of data center cooling systems.

With reference to FIGS. 1A and 1B, if an electronic system 134 comprises high power consumption devices, and/or high density arrays of electronic devices 100, such as are generally present in data centers, a circulated coolant is typically used to cool the electronic device or devices 100. According to this approach, the coolant is delivered to the electronic devices 100 by a circulation pump 106. Heat from the electronic devices 100 is thereby absorbed, and then the coolant is delivered by an exhaust pump 114 to a heat transfer apparatus 108, where the heat is extracted by a radiator, cooling tower 110, and/or a refrigeration unit 108, all of which are generically referred to herein as a “chiller” 108, which transfers the extracted heat elsewhere, for example to ambient outdoor air and/or to a facility cooling water supply 136, while the chilled coolant is recycled to the electronic devices 100. The cyclic path that is followed by the coolant, together with any pumps 106, valves, 122, gauges 132, 126, etc. is sometimes referred to herein as a cooling “loop.”

In FIG. 1A, the electronic system 134 comprises a printed circuit board 128 on which a plurality of integrated circuit “dies” 130 are mounted. A coolant 102 is circulated through a device cooling manifold 104 that is in direct thermal contact with the dies 130 of the electronic device or devices 100, where it absorbs heat and is vaporized.

A coolant control valve 122 can be used to adjust a degree of cooling of the electronic devices 100. In some cases, the valve 122 is operated manually, while in the illustrated example the valve 122 is operated by a valve controller 124, which can actuate the control valve 124 according to commands remotely input by a user, or automatically according to temperature measurements or other criteria. The example of FIG. 1A further includes a flow measuring device 132, and a plurality of temperature and pressure gauges or sensors 126.

With reference to the top view of FIG. 1B, a similar approach can be used to cool an array of electronic devices 100. According to this approach, a Coolant Distribution Unit (CDU) comprises inlet 138 and outlet 116 manifolds which circulate the coolant 102 through cooling conduits 118, such as copper pipes, which extend between and/or through the device housings 120 in thermal communication with the electronic devices 100, causing the coolant 102 to absorb heat from the electronic devices 100, and to conduct the heat to an external heat transfer apparatus, which in the illustrated example includes a refrigeration unit 108 that extracts the heat and transfers it to a cooling tower 110, from which it is dissipated into the atmosphere.

FIG. 1B illustrates a plurality of electronic devices 100 enclosed in separate housings 120 arranged in a vertical column. In similar applications, the electronic devices 100 are arranged as a grid of devices in perpendicular horizontal rows and columns. According to this approach, each electronic device 100 in FIG. 1B would be replaced by a row, or “bank,” of individual electronic device housings arranged in a horizontal row from left to right. In still other applications, a three-dimensional “matrix” of electronic devices 100 extend horizontally in rows and columns, and vertically in “tiers.”

It will be understood that a similar approach can be used to cool electronic devices 100 that are not arranged in rows and/or columns. It will also be understood that, unless otherwise stated or required by context, terms such as “electronic device,” “electronic component,” and “server” are used generically and interchangeably herein to refer to any electronic element of an electronic system that requires cooling. It will be further noted that terms such as “array” and “device array” are used herein generically to refer to any group of electronic devices and/or components that are to be cooled, regardless of how they are physically arranged.

It will also be understood, that the refrigeration units 108 and cooling towers 110 that are included in the present drawings are intended to generically represent any external heat removal and dissipation apparatus, unless otherwise stated or required by context, and are not meant to limit the invention to a specific heat dissipation apparatus design.

In the examples of FIGS. 1A and 1B, the coolant 102 is uniformly distributed among all of the electronic devices 100. This approach essentially assumes that each of the electronic devices 100 will have substantially the same heat output. However, in general, the electronic devices 100 may not all be identical to each other. And even if they are identical electronically, the heat that is generated by each of the electronic devices 100 may vary among the devices 100, and may also vary over time, according to the workload that is placed upon each of the devices 100. This can lead to temperature variations, and to “hotspots,” within the electronic system 134. In such cases, if insufficient cooling is applied to the hotspots, the electronic devices 100 in the hotspots will consume excess power and operate less efficiently.

Accordingly, if there are “hotspots” among the electronic devices 100 that create local regions of high heat dissipation, it may be necessary to compensate for the hotspots by increasing the overall flow of the coolant 102 throughout the electronic system 134, thereby providing the required amount of cooling to the hotspots, while providing an excess of cooling to other regions of the system 134. While effective, this approach can be wasteful of energy, and can require an expensive “overdesign” of the cooling system, whereby the total cooling capacity significantly exceeds the total amount of heat that will ever be generated within the system 134. Also, when the circulation of the coolant is increased until the hotspot(s) is/are sufficiently cooled, thereby applying more cooling to other regions than is needed, the temperature of the effluent coolant from the device array 100 will be reduced, thereby decreasing the efficiency of the heat dissipation apparatus 108, 110.

What is needed, therefore, is an electronic device cooling apparatus that can provide optimal cooling to a system of electronic devices, while reducing the energy consumption and cooling capacity of the cooling system, and thereby providing energy efficient operation of the device cooling apparatus.

### SUMMARY OF THE INVENTION

The present invention is an electronic device cooling apparatus that provides optimal cooling to electronic devices, while also optimizing the overall energy efficiency of the cooling system. In embodiments, the present invention provides flexible cooling that is adaptable to heat dissipation requirements that vary among the electronic devices and/or change with time.

According to the present invention, rather than relying entirely on an external chiller or other cooling apparatus to remove heat from a coolant, the present invention implements Joule-Thompson cooling directly within the electronic system. In embodiments, a plurality of coolant outlets are provided at selected locations within the electronic system. Each cooling outlet is configured to receive a pressurized coolant gas, such as CO2, and to expel the gas toward the electronic devices through a cooling constriction, such as a fixed orifice or a variable passage formed by a control valve. Expansion of the coolant gas as it is expelled from each of the cooling outlets causes the gas to be cooled according to the Joule-Thompson effect. The outlets can be positioned immediately above selected electronic devices, selected regions within the system, and/or arranged in a distributed pattern, according to a heat dissipation pattern of the electronic devices.

By cooling the coolant gas immediately in the vicinity of the electronic devices, embodiments of the present invention eliminate the need for a separate coolant chiller or other active cooling device, relying instead on passive radiators to dissipate heat from the coolant gas. In other embodiments, a separate, active cooling device is included, but reduced demands are placed on the separate cooling device due to the cooling provided by the localized Joule-Thompson cooling.

Embodiments enable a controller to adjust the degree and distribution of Joule-Thompson cooling according to changing requirements of the system. In some of these embodiments, the cooling outlets are valves that are adjusted by the controller to increase or decrease the Joule-Thompson cooling at each cooling outlet. In other embodiments, the controller adjusts the pattern of Joule-Thompson cooling by controlling a plurality of pressure or flow valves that regulate the flow of the coolant gas to various ones or groups of the cooling outlets. In still other embodiments, variable speed pressurizing pumps, such as variable frequency drive (VFD) pumps, are adjusted by the controller to vary the pressures, and thereby the degree of Joule-Thompson cooling, at various ones or groups of the cooling outlets.

Some embodiments include intermediate Joule-Thompson cooling, whereby the coolant gas is directed through an intermediate cooling constriction, such as an expansion valve, whereby the coolant gas is pre-cooled by Joule-Thompson expansion, before being further cooled a second time by Joule-Thompson expansion as it is expelled through the cooling constrictions of the cooling outlets.

In some embodiments, all of the electronic devices are cooled by a single cooling loop, while in other embodiments a plurality of cooling loops are implemented. Similarly, in embodiments, at least one of the cooling loops is branched, having a plurality of flow paths. The relative cooling provided by the plurality of cooling loops and/or cooling branches can be controlled by dedicating a controller-adjusted valve and/or variable speed pump to each loop and/or branch, thereby concentrating the cooling where it is needed among the electronic devices, and adjusting the cooling distribution as needed due to changes in the cooling requirements over time.

In some embodiments, the gas that is expelled by the cooling outlets impinges directly on one or more of the electronic devices. In other embodiments, the coolant gas impinges on dry heat sinks that are in thermal communication with one or more of the electronic devices. In still other embodiments, the Joule-Thompson cooled gas works in conjunction with a thin evaporative layer of a cooling liquid that is applied to the devices and/or to heat sinks that are in thermal communication with the devices. According to this approach, the Joule-Thompson cooling augments the effect of the cooling liquid, such that it becomes unnecessary to recycle and manage a large phase-changed fluid. Instead, a thin film of the cooling liquid can be applied to the electronic devices and/or heat sinks, which is then evaporated and removed by the coolant gas.

In various embodiments, adjustment of the Joule-Thompson cooling can be reactive, predictive, or both. In some reactive embodiments, the controller receives temperature measurements from sensors at one or more locations within the system of electronic devices. In some of these embodiments, at least one of the temperature measurements is provided by a sensor that is integral to an integrated circuit (IC), such as a central processing unit (CPU), and is configured to report a temperature of the IC. Other embodiments include at least one temperature sensor configured to measure a local temperature of the coolant gas or ambient air. Embodiments include a flow measuring device that provides data to the controller useful for directly or indirectly determining and/or controlling the rate of heat removal from the electronic devices.

In some predictive embodiments, the controller is able to adjust the operating speeds of the coolant pumps in advance of any actual changes in electronic device temperature, and in some embodiments also in advance of any actual changes in power consumption by the electronic devices, thereby minimizing or avoiding temperature fluctuations of the electronic devices, and providing increased longevity and improved operational stability of the devices. In some of these embodiments, changes in the heat output of the electronic devices are anticipated by monitoring the amount of current that is drawn by at least one of the electronic devices, such as by one or more servers. This approach is predictive, in that an increase in current usage, and a consequent increase in heat dissipation, generally precedes the resultant rise in device temperature.

In other embodiments where predictive control is implemented, local variations in heat generation within the device array are predicted according to anticipated changes in the workloads that each electronic device will be subjected to. For example, an anticipated workload can be inferred from network activity, and/or on from an internal server scheduler that queues tasks to be performed by the electronic devices. Both are normally precursors to an incoming request for processing of data that will result in a spike in the activity of a server or other electronic device, and hence an increase in heat dissipation.

The present invention is a cooling system configured to cool a plurality of electronic devices. The cooling system includes at least one cooling loop through which a coolant gas can flow through a coolant flow path into proximity and thermal communication with the electronic devices, and a cooling outlet included in the cooling loop proximate at least one of the electronic devices. The cooling outlet includes a cooling constriction, and is configured to cool the coolant gas by Joule-Thompson expansion of the coolant gas as it passes through the cooling constriction, and to direct the cooled coolant gas toward at least one of the electronic devices, thereby absorbing heat from the at least one electronic device.

In embodiments, the cooling constriction is an orifice having a fixed cross-sectional area, or a valve that forms a cooling constriction of variable cross-sectional area. In some of these embodiments, the valve is remotely controlled by a controller.

In any of the above embodiments, the cooling loop can further include at least one coolant gas pressure and/or flow control device. In some of these embodiments at least one of the coolant gas pressure and/or flow control devices is a control valve. In any of these embodiments, at least one of the coolant gas pressure and/or flow control devices can be a variable speed pump. In any of these embodiments, at least one of the coolant gas pressure and/or flow control devices can be remotely controlled by a controller. In any of these embodiments, the cooling loop can include a plurality of branches forming a plurality of coolant flow paths, and wherein each of the branches includes at least one of the coolant gas pressure and/or flow control devices. And in any of these embodiments the cooling loop can further include a coolant flow rate measurement device in data communication with the controller, and the controller can be configured to determine and/or adjust a rate of heat removal from the electronic device at least in part according to flow rate data received from the coolant flow rate measurement device.

In any of the above embodiments, the cooling outlet can be configured to direct the cooled coolant gas toward a dry heat sink in thermal communication with at least one of the electronic devices.

In any of the above embodiments, the cooling system can further include a liquid coolant application system configured to apply a film of a liquid coolant either directly to at least one of the electronic devices or to at least one heat sink that is in thermal communication with the at least one of the electronic devices, and the cooling outlet can be configured to direct the cooled coolant gas toward the film of liquid coolant. In some of these embodiments, the liquid coolant delivery system is configured to produce the cooling liquid by liquifying a portion of the coolant gas that is diverted to the liquid coolant application system from the coolant flow path.

In any of the above embodiments, the coolant flow path can further include an intermediate cooling constriction configured to pre-cool the coolant gas by Joule-Thompson expansion, before the coolant gas is further cooled by Joule-Thompson expansion as it is expelled through the cooling outlet. In some of these embodiments the intermediate cooling constriction is formed by an intermediate valve, a cross-sectional area of the intermediate cooling constriction being variable thereby. In some of these embodiments the intermediate valve is remotely controlled by a controller.

In any of the above embodiments, the cooling system can include a plurality of cooling loops, each of the cooling loops being configured to direct the coolant gas through at least one coolant flow path into proximity and thermal communication with at least one of the electronic devices. In some of these embodiments, at least one of the cooling loops comprises at least one pressure and/or flow control device, each of the pressure and/or flow control devices being selected from the group consisting of a control valve and a variable speed pump. And in some of these embodiments, at least one of the pressure and/or flow control devices is remotely controlled by a controller.

And any of the above embodiments can include a heat dissipation device configured to reduce a temperature of the coolant gas after it has absorbed the heat from the at least one electronic device.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1A illustrates a single cooling loop of the prior art in which the coolant flow rate is controlled by a flow control valve;

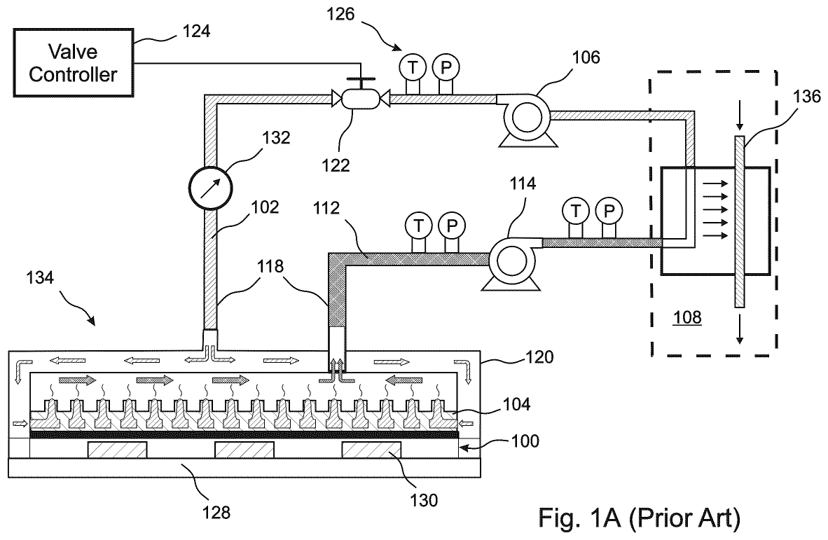

FIG. 1B illustrates a branched cooling loop of the prior art;

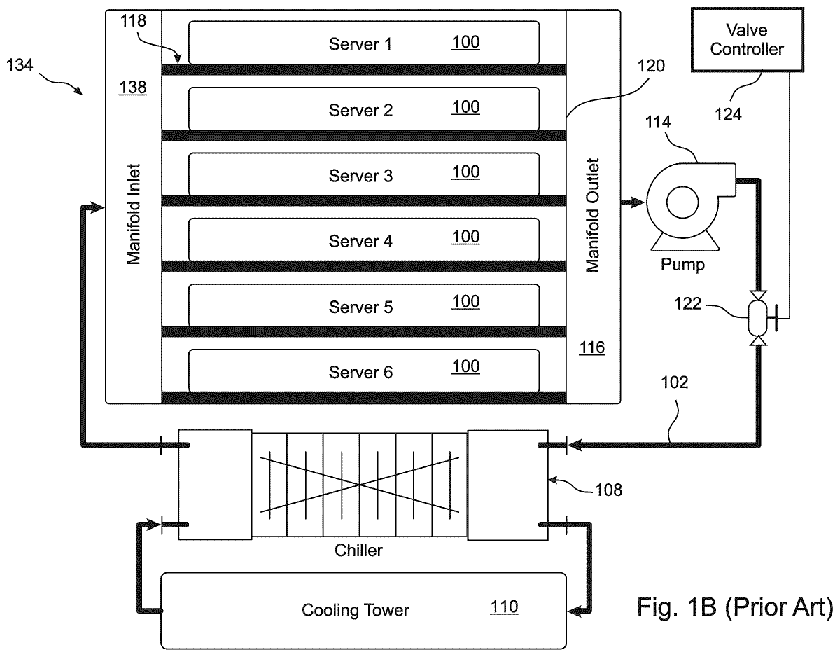

FIG. 2 illustrates a single cooling loop in an embodiment of the present invention in which the coolant gas is pre-cooled by an intermediate cooling constriction and wherein the cooling outlets are remotely controlled valves;

FIG. 3A illustrates an embodiment that implements a single, branched cooling loop wherein the cooling outlets are fixed orifices, and the flow rates in the branches are adjusted by remotely controlled valves;

FIG. 3B illustrates an embodiment similar to FIG. 3A in which the cooling loop branches are directed to a plurality of separately housed servers;

FIG. 4 illustrates an embodiment that implements a single, branched cooling loop wherein the cooling outlets are fixed orifices, and the flow rates in the branches are adjusted by remotely controlled variable speed pumps; and

FIG. 5 illustrates an embodiment that implements a plurality of cooling loops, each including a dedicated, remotely controlled variable speed pump.

### DETAILED DESCRIPTION

The present invention is an electronic device cooling system that provides optimal cooling to electronic devices, while also optimizing the overall energy efficiency of the cooling system. In embodiments, the present invention provides flexible cooling that is adaptable to heat dissipation requirements that change with time.

According to the present invention, rather than relying entirely on an external chiller or other cooling apparatus to remove heat from a coolant, the present invention implements Joule-Thompson cooling directly within the electronic system.

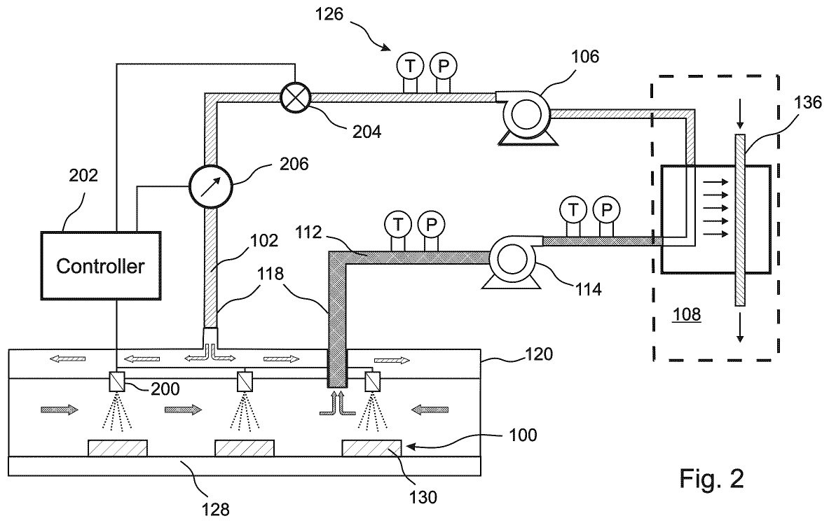

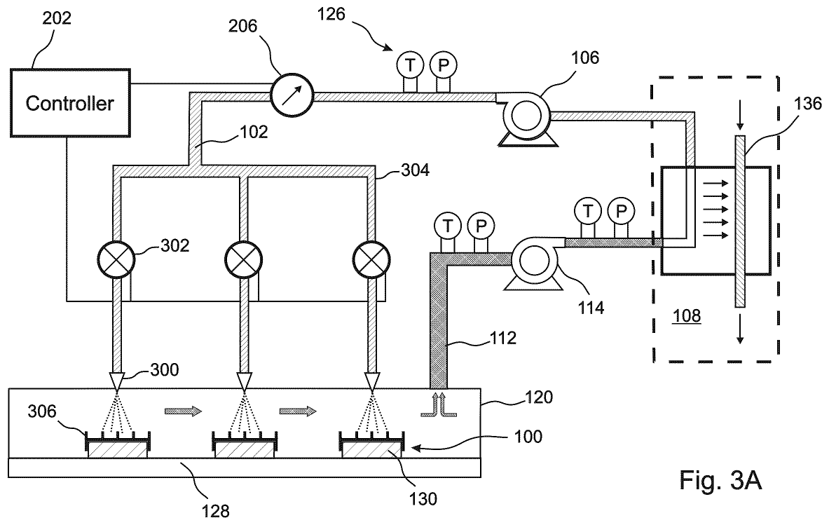

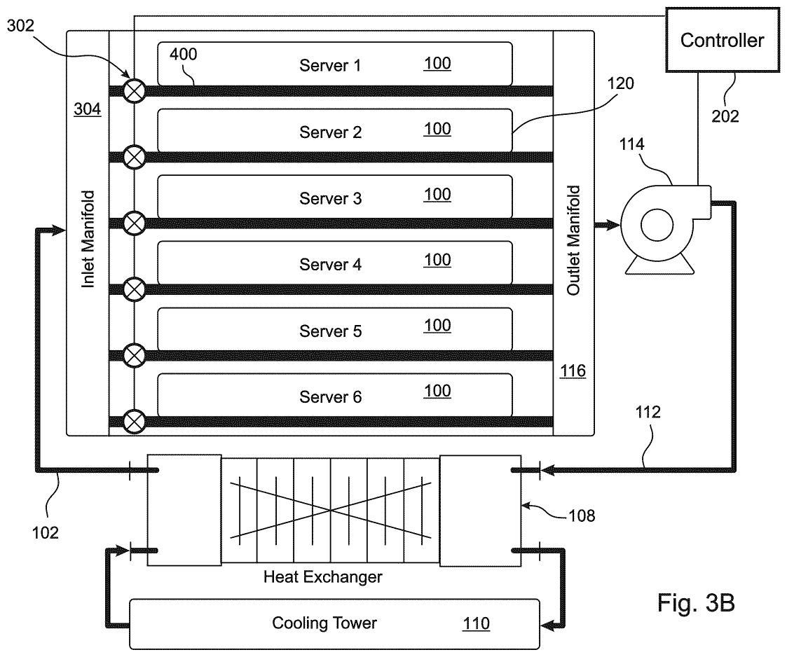

With reference to FIGS. 2 and 3, a plurality of coolant outlets 200, 300 are provided at selected locations within the electronic system. Each cooling outlet 200, 300 is configured to receive a pressurized coolant gas 102, such as CO2, and to expel the gas 102 toward the electronic devices 100 through a cooling constriction. Expansion of the coolant gas 102 as it is expelled from each of the cooling outlets causes the gas 102 to be cooled according to the Joule-Thompson effect. The outlets can be positioned immediately above selected electronic devices 100, above selected regions within the system, and/or arranged in a distributed pattern, according to a heat dissipation pattern of the electronic devices.

By applying Joule-Thompson to the coolant gas 102 immediately in the vicinity of the electronic devices 100, embodiments of the present invention eliminate the need for a separate active coolant chiller 108 or other cooling device, relying instead on passive radiators and/or cooling towers 110 to dissipate heat from the coolant gas. In the embodiments of FIGS. 2 and 3, an active cooling device 108 is included, but reduced demands are placed on the active cooling device 108 due to the cooling provided by the localized Joule-Thompson expansion.

In some embodiments, the cooling outlets 300 include cooling constrictions that are orifices having fixed cross-sectional areas. The fixed cooling constrictions of all of the cooling outlets 300 can be the same in cross-sectional area, or varied in area according to a distribution of anticipated cooling requirements among the devices 100.

In FIG. 2, the cooling constrictions are formed by flow restricting valves 200 that are adjustable by a controller 202 to increase or decrease the Joule-Thompson cooling at each cooling outlet 200, thereby enabling the controller 202 to adjust the degree and distribution of Joule-Thompson cooling according to changing requirements of the system. The embodiment of FIG. 2 further includes intermediate Joule-Thompson cooling, whereby the coolant gas 102 is directed through an intermediate cooling constriction, which can be an expansion valve 204, whereby the coolant gas 102 is pre-cooled by intermediate Joule-Thompson expansion, before being further cooled by Joule-Thompson expansion as it is expelled through the cooling outlets 200.

In the embodiments of FIGS. 3A and 3B, the coolant gas 102 is distributed by an inlet manifold 304 into cooling branches directed to various ones or groups of cooling outlets 300 having fixed cooling constrictions, and the controller 202 adjusts the pattern of Joule-Thompson cooling by controlling a plurality of pressure or flow valves 302 associated with each of the cooling branches. In similar embodiments, the cooling outlets 300 themselves are remotely controlled valves. In FIG. 3A, all of the cooling outlets 300 are directed into the same device housing 120, within which the coolant gas is merged into a common exhaust flow 112. In FIG. 3B, the cooling branches are directed to a plurality of separately housed servers 120, from which the coolant gas is subsequently combined by an outlet manifold 116 into a common exhaust flow 112.

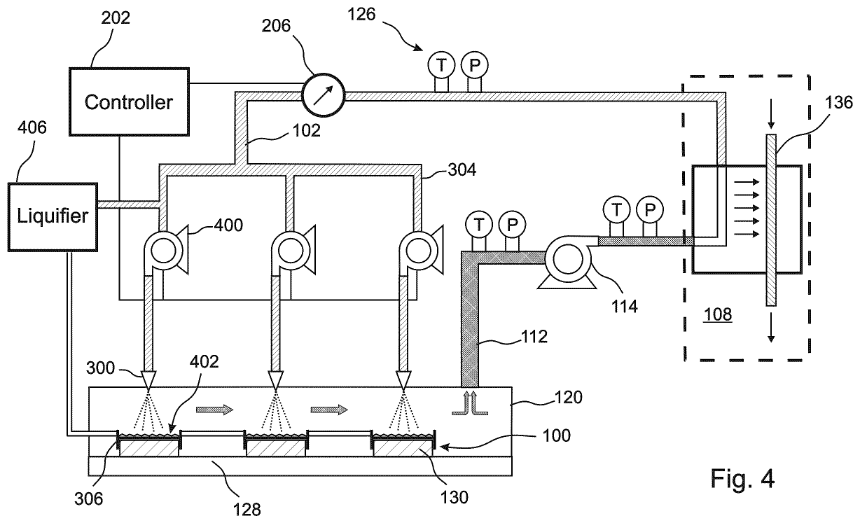

With reference to FIG. 4, in similar embodiments a separate variable speed pressurizing pump 400, such as a variable frequency drive (VFD) pump, is associated with each of the cooling branches and is separately adjusted by the controller 202 to vary the coolant gas pressure, and thereby the degree of Joule-Thompson cooling, at various ones or groups of the cooling outlets 300.

In the embodiment of FIG. 2, all of the electronic devices 100 are cooled by a single cooling loop having a single flow path, while in the embodiments of FIGS. 3A-4, the cooling loop is branched, having a plurality of separately controlled flow paths that flexibly concentrate the cooling where it is needed among the electronic devices 100.

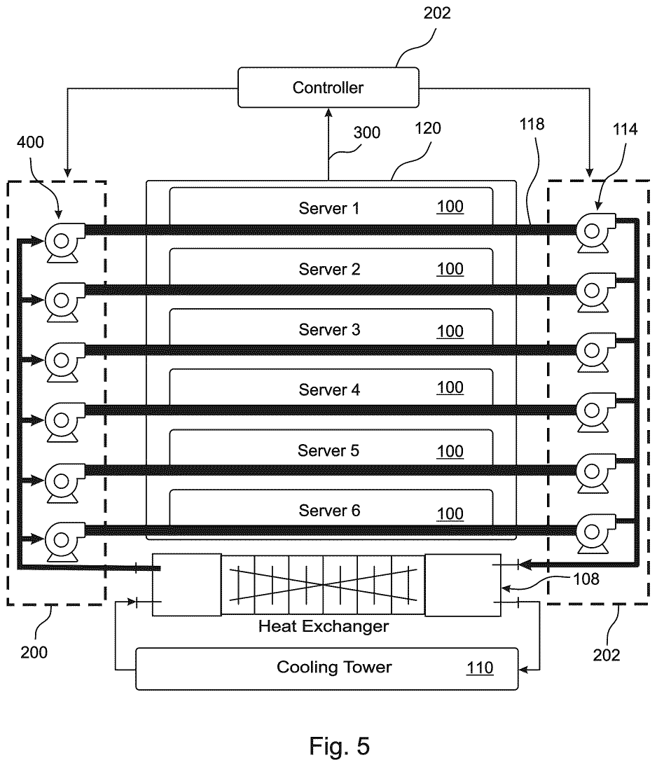

With reference to FIG. 5, in other embodiments a plurality of cooling loops are implemented. In the illustrated embodiment, a separate inlet pump 400 and outlet pump 114 is provided for each of the cooling loops. In the embodiment of FIG. 5, both the inlet pumps 400 and the outlet pumps 114 are variable speed pumps, such as variable frequency pumps, having operating speeds that are controlled by the controller 202.

With reference again to FIG. 2, in some embodiments, the gas that is expelled by the cooling outlets 20 impinges directly on one or more of the electronic devices 100. With reference again to FIG. 3A, in other embodiments the coolant gas impinges onto dry heat sinks 306 that are in thermal communication with one or more of the electronic devices 100.

With reference again to FIG. 4, in still other embodiments, the Joule-Thompson cooled gas works in conjunction with a thin evaporative layer 402 of a cooling liquid that is applied to the devices 100 and/or to heat sinks 306 that are in thermal communication with the devices 100. According to this approach, the Joule-Thompson cooling augments the effect of the cooling liquid 402, such that it becomes unnecessary to recycle and manage a large volume of a cooling liquid. Instead, a thin film of the cooling liquid 402 is applied to the electronic devices 100 and/or heat sinks 306, which is then evaporated and removed together with the coolant gas 112. In the embodiment of FIG. 4, the cooling liquid 402 is provided by a liquefier 406 to which a small portion of the coolant gas 102 is diverted.

In various embodiments where the Joule-Thompson cooling is adjustable by a controller 202, the adjustment can be reactive, predictive, or both. In some reactive embodiments, the controller 202 receives temperature measurements from sensors 126 at one or more locations within the system of electronic devices 100. In some of these embodiments, at least one of the temperature measurements is provided by a sensor that is integral to an integrated circuit (IC), such as a central processing unit (CPU), and is configured to report a temperature of the IC. Other embodiments include at least one temperature sensor configured to measure a local temperature of the coolant gas or ambient air. Embodiments include a flow measuring device 206 that provides data to the controller 202 useful for directly or indirectly determining and/or controlling the rate of heat removal from the electronic devices 100.

In some predictive embodiments, the controller 202 is able to adjust the rate of Joule-Thompson cooling in advance of any actual changes in electronic device temperature, and in some embodiments also in advance of any actual changes in power consumption by the electronic devices, thereby minimizing or avoiding temperature fluctuations of the electronic devices 100, and providing increased longevity and improved operational stability of the devices 100. In some of these embodiments, changes in the heat output of the electronic devices 100 are anticipated by monitoring the amount of current that is drawn by at least one of the electronic devices 100, such as by one or more servers. This approach is predictive, in that an increase in current usage, and a consequent increase in heat dissipation, generally precedes the resultant rise in device temperature.

In other embodiments where predictive control is implemented, local variations in heat generation within the device array 100 are predicted according to anticipated changes in the workload that each electronic device 100 will be subjected to. For example, an anticipated workload can be inferred from network activity, and/or on from an internal server scheduler that queues tasks to be performed by the electronic devices 100. Both are normally precursors to an incoming request for processing of data that will result in a spike in the activity of a server or other electronic device 100, and hence an increase in heat dissipation.

The foregoing description of the embodiments of the invention has been presented for the purposes of illustration and description. Each and every page of this submission, and all contents thereon, however characterized, identified, or numbered, is considered a substantive part of this application for all purposes, irrespective of form or placement within the application. This specification is not intended to be exhaustive or to limit the invention to the precise form disclosed. Many modifications and variations are possible in light of this disclosure.

Although the present application is shown in a limited number of forms, the scope of the disclosure is not limited to just these forms, but is amenable to various changes and modifications. The present application does not explicitly recite all possible combinations of features that fall within the scope of the disclosure. The features disclosed herein for the various embodiments can generally be interchanged and combined into any combinations that are not self-contradictory without departing from the scope of the disclosure. In particular, the limitations presented in dependent claims below can be combined with their corresponding independent claims in any number and in any order without departing from the scope of this disclosure, unless the dependent claims are logically incompatible with each other.

What is claimed is:

1. A cooling system configured to cool a plurality of electronic devices, the cooling system comprising:
at least one cooling loop through which a coolant gas can flow through a coolant flow path into proximity and thermal communication with the electronic devices; and
a cooling outlet included in the cooling loop proximate at least one of the electronic devices, the cooling outlet comprising a cooling constriction, the cooling outlet being configured to cool the coolant gas by Joule-Thompson expansion of the coolant gas as it passes through the cooling constriction, and to direct the cooled coolant gas toward at least one of the electronic devices, thereby absorbing heat from the at least one electronic device.

2. The cooling system of claim 1, wherein the cooling constriction is an orifice having a fixed cross-sectional area.

3. The cooling system of claim 1, wherein the cooling outlet is a valve that forms a cooling constriction of variable cross-sectional area.

4. The cooling system of claim 3, wherein the valve is remotely controlled by a controller.

5. The cooling system of claim 1, wherein the cooling loop further includes at least one coolant gas pressure and/or flow control device.

6. The cooling system of claim 5, wherein at least one of the coolant gas pressure and/or flow control devices is a control valve.

7. The cooling system of claim 5, wherein at least one of the coolant gas pressure and/or flow control devices is a variable speed pump.

8. The cooling system of claim 5, wherein at least one of the coolant gas pressure and/or flow control devices is remotely controlled by a controller.

9. The cooling system of claim 5, wherein the cooling loop comprises a plurality of branches forming a plurality of coolant flow paths, and wherein each of the branches includes at least one of the coolant gas pressure and/or flow control devices.

10. The cooling system of claim 5, wherein the cooling loop further includes a coolant flow rate measurement device in data communication with the controller, and where the controller is configured to determine and/or adjust a rate of heat removal from the electronic device at least in part according to flow rate data received from the coolant flow rate measurement device.

11. The cooling system of claim 1, wherein the cooling outlet is configured to direct the cooled coolant gas toward a dry heat sink in thermal communication with at least one of the electronic devices.

12. The cooling system of claim 1, wherein:
the cooling system further comprises a liquid coolant application system configured to apply a film of a liquid coolant either directly to at least one of the electronic devices or to at least one heat sink that is in thermal communication with the at least one of the electronic devices; and
the cooling outlet is configured to direct the cooled coolant gas toward the film of liquid coolant.

13. The cooling system of claim 12, wherein the liquid coolant delivery system is configured to produce the cooling liquid by liquifying a portion of the coolant gas that is diverted to the liquid coolant application system from the coolant flow path.

14. The cooling system of claim 1, wherein the coolant flow path further comprises an intermediate cooling constriction configured to pre-cool the coolant gas by Joule-Thompson expansion, before the coolant gas is further cooled by Joule-Thompson expansion as it is expelled through the cooling outlet.

15. The cooling system of claim 14, wherein the intermediate cooling constriction is formed by an intermediate valve, a cross-sectional area of the intermediate cooling constriction being variable thereby.

16. The cooling system of claim 15, wherein the intermediate valve is remotely controlled by a controller.

17. The cooling system of claim 1, wherein the cooling system comprises a plurality of cooling loops, each of the cooling loops being configured to direct the coolant gas through at least one coolant flow path into proximity and thermal communication with at least one of the electronic devices.

18. The cooling system of claim 17, wherein at least one of the cooling loops comprises at least one pressure and/or flow control device, each of the pressure and/or flow control devices being selected from the group consisting of a control valve and a variable speed pump.

19. The cooling system of claim 18, wherein at least one of the pressure and/or flow control devices is remotely controlled by a controller.

20. The cooling system of claim 1, further comprising a heat dissipation device configured to reduce a temperature of the coolant gas after it has absorbed the heat from the at least one electronic device.
